(19) United States
(12) Patent Application Publication
(10) Pub. No.: US 2026/0172039 A1
(43) Pub. Date: Jun. 18, 2026

(54) Method For Generating Fractional-N Clock, Fractional-N Phase-Locked Loops With Dual Detection Paths And Integrated Circuit

(71) Applicant: MediaTek Inc., Hsinchu City (TW)

(72) Inventors: Shuja Hussain Andrabi, Cambridge (GB); Arnaud Serge Pierre Werquin, Cambridge (GB); Samarth Vasishtha, Cambridge (GB)

(73) Assignee: MediaTek Inc., Hsinchu City (TW)

(21) Appl. No.: 19/357,114

(22) Filed: Oct. 14, 2025

Related U.S. Application Data
(60) Provisional application No. 63/734,795, filed on Dec. 17, 2024.

(51) Int. Cl. H03L 7/197; H03L 7/081; H03L 7/087; H03L 7/099

(52) U.S. Cl. CPC H03L 7/1976; H03L 7/081; H03L 7/087; H03L 7/099

(57) ABSTRACT

Various solutions for generating fractional-N clock, phase-locked loops (PLL) with dual detection paths, and integrated circuits thereof are described. The method involves a PLL circuit performing a first subsampling process to sample a clock signal using a reference signal, and generating a first sampled signal. A compensation signal is generated from a digital-to-time conversion circuit based on a compensation code and the reference signal. A second subsampling process samples this compensation signal using the reference signal to produce a second sampled signal. These two sampled signals are then converted using a first and a second transconductance gain, respectively, to obtain two transconductance signals. A fractional-N phase error signal is generated from the difference between the two transconductance signals.

### CROSS REFERENCE TO RELATED PATENT APPLICATION(S)

The present disclosure is part of a non-provisional application claiming the priority benefit of U.S. Patent Application No. 63/734,795, filed 17 Dec. 2024, the content of which herein being incorporated by reference in its entirety.

### TECHNICAL FIELD

The present disclosure is generally related to phase-locked loops and, more particularly, to a method for generating a fractional-N clock, a fractional-N phase-locked loop (PLL) with dual detection paths and an integrated circuit using the same.

### BACKGROUND

Unless otherwise indicated herein, approaches described in this section are not prior art to the claims listed below and are not admitted as prior art by inclusion in this section.

The Fractional-N Phase-Locked Loop (Fractional-N PLL) is an essential component in modern high-speed, high-resolution clock generators and frequency synthesizers. It enables finer frequency control compared to integer-N PLLs and is widely used in systems such as wireless communications (e.g., LTE, 5G), high-speed analog-to-digital converter/digital-to-analog Converter (ADC/DAC) clocks, and SerDes. In a traditional integer-N PLL, the output frequency is given by f_out=N×f_ref, where N is an integer and f_ref is the reference frequency. The Fractional-N PLL extends this relationship to f_out=(N+α)×f_ref, where a is a fraction less than 1. This allows for non-integer frequency synthesis, significantly improving frequency resolution.

FIG. 1 illustrates a circuit diagram depicting a conventional fractional-N Phase-Locked Loop (PLL). Referring to FIG. 1, a fractional-N PLL may include a digital-to-time conversion circuit DTC, a subsampling phase detector SSPD, a transconductance amplifier GM, a loop filter LF, and a voltage-controlled oscillator VCO. The digital-to-time conversion circuit DTC receives the input reference signal REF and a control signal SDM to output an adjusted reference signal AREF. The subsampling phase detector SSPD receives the adjusted reference signal AREF and the voltage-controlled clock signal OSC received from the voltage-controlled oscillator VCO. The voltage-controlled clock signal OSC is sub-sampled by the adjusted reference signal AREF to generate a subsampled phase difference signal SPDS. The transconductance amplifier GM receives the subsampled phase difference signal SPDS to convert it into a current driving signal to drive the loop filter LF. The voltage-controlled oscillator VCO adjusts the frequency of the voltage-controlled clock signal OSC according to the output signal of the loop filter LF.

However, when the PLL bandwidth increases, it passes more noise to the output. In a fractional-N PLL, the quantization noise of the digital-to-time conversion circuit DTC is one of the main noise sources. This means that if the PLL bandwidth is designed too high, more quantization noise of the digital-to-time conversion circuit DTC will be transferred to the output, resulting in increased jitter. To meet a specific noise target, the increase in PLL bandwidth is limited by the quantization noise of the digital-to-time conversion circuit DTC. Therefore, the quantization noise of the digital-to-time conversion circuit DTC sets an upper limit on the PLL bandwidth. This also leads to higher power consumption in the voltage-controlled oscillator VCO.

Furthermore, under a fixed noise target, the increase in PLL bandwidth is also limited by the thermal noise and the reference clock noise of the digital-to-time converter DTC. The PLL loop behaves as a low-pass filter for the reference clock noise, meaning that noise within the PLL bandwidth will be passed to the output. Therefore, to maintain a specific noise level, the increase in PLL bandwidth must not exceed the limits imposed by reference clock noise and the thermal noise of the digital-to-time conversion circuit DTC. If the bandwidth is too wide, these noises will be passed to the output, causing the overall noise to exceed the target.

To achieve lower overall noise, the voltage-controlled oscillator VCO must maintain low phase noise outside the PLL bandwidth. However, keeping the voltage-controlled oscillator VCO noise low over a wider frequency range typically requires higher power consumption of the voltage-controlled oscillator VCO. In conventional technologies, factors such as the quantization noise of the digital-to-time conversion circuit DTC limit the PLL bandwidth, preventing the PLL from pushing the in-band noise to higher frequencies. As a result, the PLL could not effectively suppress the noise of the voltage-controlled oscillator VCO. This forces designers to increase the power consumption of the voltage-controlled oscillator VCO in order to meet the overall noise requirements. Therefore, there is a need to provide proper solutions to resolve the aforementioned issues.

### SUMMARY

The following summary is illustrative only and is not intended to be limiting in any way. That is, the following summary is provided to introduce concepts, highlights, benefits and advantages of the novel and non-obvious techniques described herein. Select implementations are further described below in the detailed description. Thus, the following summary is not intended to identify essential features of the claimed subject matter, nor is it intended for use in determining the scope of the claimed subject matter.

An objective of the present disclosure is to propose solutions or schemes to address the aforementioned issues related to the quantization noise of the digital-to-time converter, thereby enhancing its resolution and significantly increasing the bandwidth of the PLL.

In one aspect, a method for generating a fractional-N clock is proposed. The method includes: performing a first sub-sampling process to sample a clock signal using a reference signal and to output a first sampled signal; generating a compensation signal according to a compensation code and the reference signal; performing a second sub-sampling process, to sample the compensation signal using the reference signal and to output a second sampled signal; converting the first sampled signal with a first transconductance gain to obtain a first transconductance signal; converting the second sampled signal with a second transconductance gain to obtain a second transconductance signal; generating a fractional-N phase error signal by the difference between the first transconductance signal and the second transconductance signal; and generating the clock signal using the fractional-N phase error signal.

In another aspect, an integrated circuit is proposed. The integrated circuit includes a functional circuit and a phase-locked loop (PLL) circuit. The functional circuit receives a clock signal. The PLL circuit includes a subsampling phase detection circuit, a loop-filter and a controllable oscillator. The subsampling phase detection circuit includes a first sampling circuit, a digital-to-time conversion circuit, a second sampling circuit, a first transconductance amplifier, a second transconductance amplifier and a subtractor circuit. The first sampling circuit receives a reference signal and the clock signal to sample the clock signal using the reference signal and to output a first sampled signal. The digital-to-time conversion circuit receives the reference signal to generate a fractional-N signal according to a compensation code and the reference signal. The second sampling circuit receives the reference signal and the delayed reference signal to sample the delay signal using the reference signal and to output a second sampled signal. The first transconductance amplifier receives the first sampled signal to amplify the first sampled signal with a first transconductance gain and to output a first transconductance signal. The second transconductance amplifier receives the second sampled signal to amplify the second sampled signal with a second transconductance gain and to output a second transconductance signal. The subtractor circuit receives the first transconductance signal and the second transconductance signal to generate the fractional-N phase error signal. The loop-filter receives the fractional-N phase error signal to output a control signal. The controllable oscillator receives the control signal to generate the clock signal according to the control signal.

It is noteworthy that, although description provided herein may be in the context of certain DCE sampling divider and edge adjusting technologies for PLL, the proposed concepts, schemes, and any variation(s)/derivative(s) thereof may be implemented in, for, and by other types of PLL technologies and topologies such as, for example and without limitation, Sampling PLLs, REF-Doubling PLLs, Dual-Edge Locking PLLs, PFD-CP PLLs, Sampler-Gm PLLs, All-Digital PLLs (ADPLLs), and may be applied to both Integ-N and Frac-N PLLs. Thus, the scope of the present disclosure is not limited to the examples described herein.

### BRIEF DESCRIPTION OF THE DRAWINGS

The accompanying drawings are included to provide a further understanding of the disclosure and are incorporated in and constitute a part of the present disclosure. The drawings illustrate implementations of the disclosure and, together with the description, serve to explain the principles of the disclosure. It is appreciable that the drawings are not necessarily in scale as some components may be shown to be out of proportion than the size in actual implementation in order to clearly illustrate the concept of the present disclosure.

FIG. 1 illustrates a circuit diagram depicting a conventional fractional-N Phase-Locked Loop (PLL).

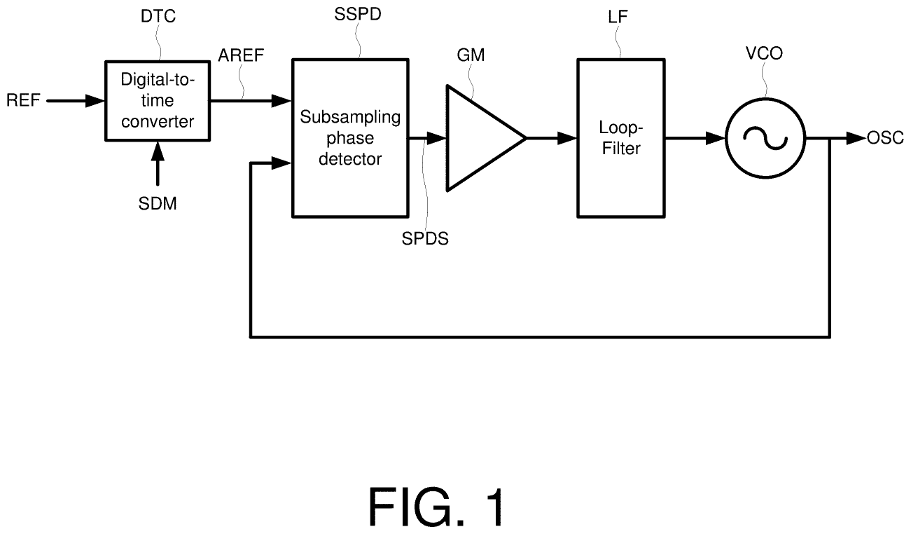

FIG. 2 illustrates an example implementation of an integrated circuit with a phase-locked loop (PLL) in accordance with the present disclosure.

FIG. 3 illustrates an example implementation of a fractional-N PLL 22 in accordance with the present disclosure.

FIG. 4 illustrates a flowchart depicting a method for generating a fractional-N clock in accordance with the present disclosure.

FIG. 5 illustrates a flowchart depicting the sub-steps of the step S408 of the method for generating a fractional-N clock in accordance with the present disclosure.

### DETAILED DESCRIPTION OF PREFERRED IMPLEMENTATIONS

Detailed embodiments and implementations of the claimed subject matters are disclosed herein. However, it shall be understood that the disclosed embodiments and implementations are merely illustrative of the claimed subject matters which may be embodied in various forms. The present disclosure may, however, be embodied in many different forms and should not be construed as limited to the exemplary embodiments and implementations set forth herein. Rather, these exemplary embodiments and implementations are provided so that description of the present disclosure is thorough and complete and will fully convey the scope of the present disclosure to those skilled in the art. In the description below, details of well-known features and techniques may be omitted to avoid unnecessarily obscuring the presented embodiments and implementations.

### Overview

Implementations in accordance with the present disclosure relate to various techniques, methods, schemes and/or solutions pertaining to a method for generating a fractional-N clock, a fractional-N PLL with dual detection paths and an integrated circuit using the same. According to the present disclosure, a number of possible solutions may be implemented separately or jointly. That is, although these possible solutions may be described below separately, two or more of these possible solutions may be implemented in one combination or another.

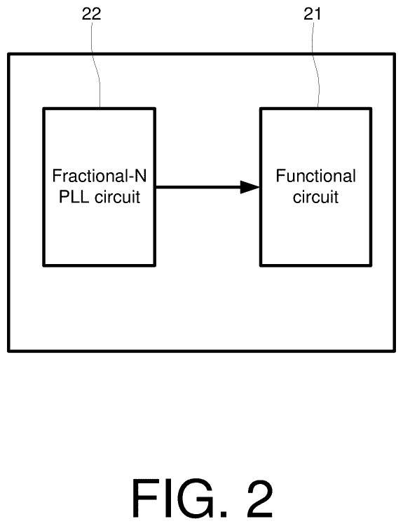

FIG. 2 illustrates an example implementation of an integrated circuit with a phase-locked loop (PLL) in accordance with the present disclosure. Referring to FIG. 2, the integrated circuit includes a functional circuit 21 and a fractional-N PLL circuit 22. The fractional-N PLL circuit 22 is coupled to the functional circuit 21 for generating a clock signal with higher frequency resolution compared to an integer-N PLL circuit.

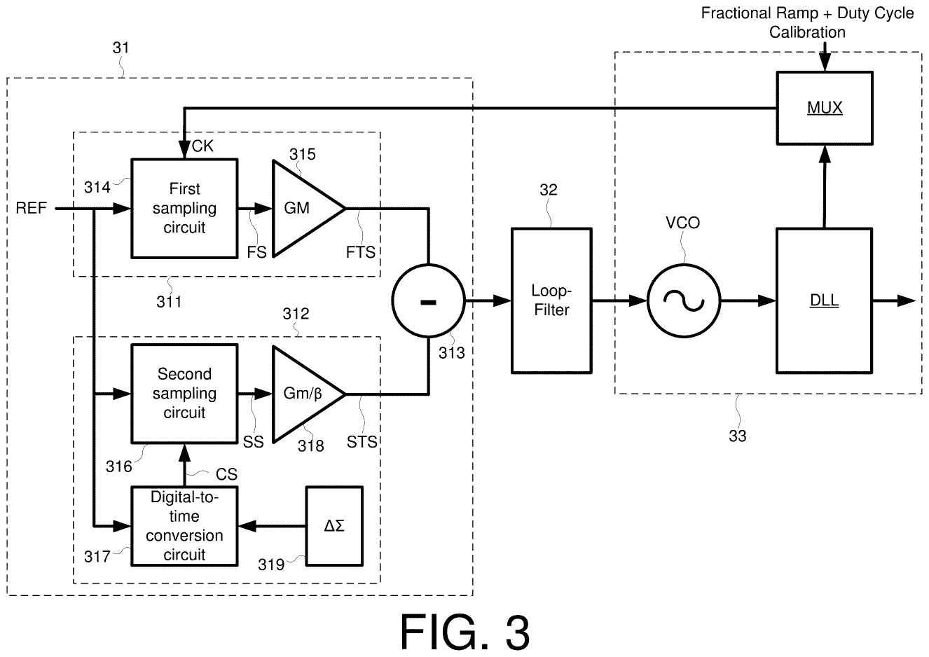

FIG. 3 illustrates an example implementation of a fractional-N PLL circuit 22 in accordance with the present disclosure. Referring to FIG. 3, the fractional-N PLL circuit 22 includes a subsampling phase detection circuit 31, a loop filter 32 and a controllable oscillator 33. In this embodiment, the controllable oscillator 33 includes a voltage-controlled oscillator VCO, a delay-locked loop DLL and a multiplexer MUX. The subsampling phase detection circuit 31 is a dual-detection path subsampling circuit. The subsampling phase detection circuit 31 includes a first detection path 311, a second detection path 312 and a subtractor circuit 313.

The first detection path 311 includes a first sampling circuit 314 and a first transconductance amplifier 315. The first sampling circuit 314 receives the reference signal REF and the clock signal CK output from the controllable oscillator 33. It is configured to sample the clock signal CK using the reference signal REF, and to output a first sampled signal FS, which represents the phase difference between the reference signal REF and the clock signal CK. The first transconductance amplifier 315 receives the first sampled signal FS, is configured to amplify the first sampled signal FS with a first transconductance gain Gm, and outputs a first transconductance signal FTS.

In this embodiment, the clock signal CK is generated by the voltage-controlled oscillator VCO, the delay-locked loop DLL and the multiplexer MUX. The voltage-controlled oscillator VCO generates the oscillation signal OS, the delay-locked loop DLL generates multiple phase signals based on the oscillation signal OS, and the multiplexer MUX selects one of the multiple phase signals to serve as the clock signal CK. The multiple-phase signals generated by the delay-locked loop DLL are designed to provide a finer phase selection, allowing for more precise time alignment. By enabling phase selection via the multiplexer MUX, the PLL can achieve high resolution, increased loop bandwidth, and reduced residual quantization error.

The second detection path 312 includes a second sampling circuit 316, a digital-to-time conversion circuit 317, a second transconductance amplifier 318 and a delta sigma modulation circuit 319. The delta sigma modulation circuit 319 is used to generate a compensation code. The digital-to-time conversion circuit 317 receives the reference signal REF and the compensation code. It is configured to generate a compensation signal CS based on the compensation code and the reference signal REF. The second sampling circuit 316 receives the reference signal REF and the compensation signal CS. It is configured to sample the compensation signal CS using the reference signal REF and to output a second sampled signal SS. The second transconductance amplifier receives the second sampled signal SS, is configured to amplify the second sampled signal SS with a second transconductance gain Gm/β, and to output a second transconductance signal STS. The subtractor circuit 313 receives the first transconductance signal FTS and the second transconductance signal STS. It is configured to generate the fractional-N phase error signal. The loop filter 32 filters the fractional-N phase error signal and outputs it to control the oscillation signal OS output from the VCO.

In this embodiment, to generate a fractional-N signal, the implementation is divided into two signal-generating loop paths. The first loop path includes a first detection path 311, the loop filter 32, and the controllable oscillator 33. The second loop path includes a second detection path 312, the loop filter 32, and the controllable oscillator 33. In this dual-loop architecture, one path might generate a fractional-N signal with its inherent quantization noise. The other path may employ a digital-to-time conversion circuit 317 to handle the first path quantization error component. By utilizing a cancellation technique, such as a subtractor circuit 313, the quantization noise generated in the first path 311 is reduced and shaped to a higher frequency, where it can be effectively attenuated by the loop filter 32. This allows the PLL to be implemented with a wider loop bandwidth, enabling more effective suppression of low-frequency oscillator noise, including VCO phase noise, noise induced by temperature variations, power supply fluctuations, and other slow-varying disturbances. As a result, the overall jitter performance can be significantly improved.

Moreover, it is noted that the second transconductance amplifier has the second transconductance gain being equal to Gm/β. The denominator β is a resolution amplification factor, which is used to determine the resolution of the compensation signal. Due to the reduced gain in the separate path, the step size of the digital-to-time conversion circuit 317 is increased by a factor of p to maintain the same overall resolution. In other words, if the digital-to-time conversion circuit 317 has a step size of two picoseconds and the designed denominator β is 4, then the effective resolution of the digital-to-time conversion circuit 317 would be 500 femtoseconds, which is two picoseconds divided by p. This method therefore reduces quantization noise and enhances the resolution of the digital-to-time conversion circuit 317.

Additionally, the thermal noise of the digital-to-time conversion circuit 317 is also reduced by the factor β. The thermal noise of the digital-to-time conversion circuit 317 is proportional to the square root of the delay, and can be expressed as:

$${DTC}_{thermalNoise} = \frac{{DTC}_{thermalNoise}}{\sqrt{β}} .$$

Since the delay increases by a factor of β and the gain is attenuated by the same factor, the noise is effectively divided by \sqrt{β}. Thus, the denominator β improves both the resolution and the noise performance of the digital-to-time conversion circuit 317.

In the above embodiment, the delay-locked loop circuit DLL and the multiplexer MUX are used to illustrate a possible implementation. However, they could be replaced by any other block/circuit capable of performing digital-to-time or analog-to-time (or phase) conversion, which can modulate the feedback phase based on the fractional ramp+duty cycle signal. Therefore, the present invention is not limited thereto. Furthermore, even in an extreme case where the DLL circuit and the MUX are removed and the voltage-controlled oscillator VCO is directly coupled to the first sampling circuit 314, the PLL can still operate, although system performance may be negatively impacted. Thus, the present invention is not limited thereto.

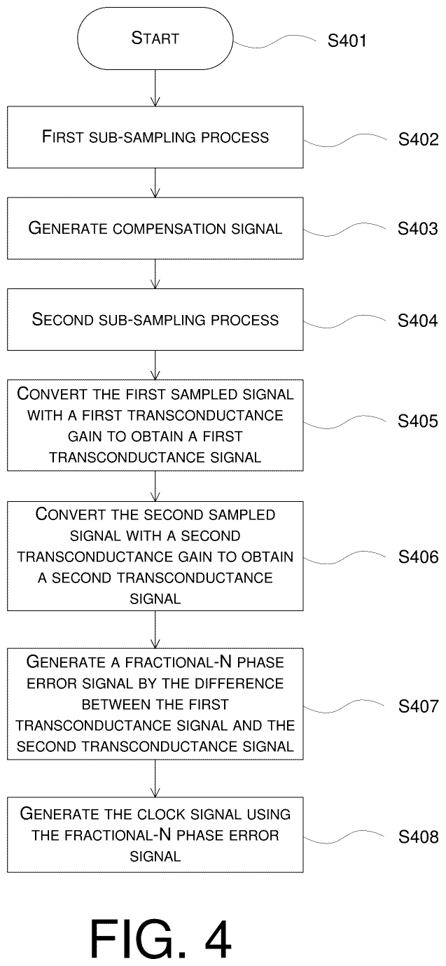

FIG. 4 illustrates a flowchart depicting a method for generating a fractional-N clock in accordance with the present disclosure. Referring to FIG. 4, in this implementation, the method includes the following steps.

In step S401, the method starts.

In step S402, a first sub-sampling process is performed to sample a clock signal using the reference signal and to output a first sampled signal.

In step S403, a compensation signal is generated according to a compensation code and the reference signal. In the abovementioned embodiment, the compensation code can be generated by a delta sigma modulation circuit 319. The compensation code, together with the reference signal REF, is then input into a digital-to-time conversion circuit 317 to generate the compensation signal CS. In particular, the digital-to-time conversion circuit 317 delays the reference signal REF under the control of the delta sigma modulation circuit 319, which modulates the residual error from the fractional ramp. This delayed reference signal serves as the compensation signal CS.

In step S404, a second sub-sampling process is performed to sample the compensation signal using the reference signal and to output a second sampled signal. Subsequently, a second sub-sampling process is performed, in which the residual delayed reference signal (the compensation signal CS) is sampled using the reference signal REF, thereby outputting a second sampled signal.

In step S405, the first sampled signal is converted with a first transconductance gain to obtain a first transconductance signal.

In step S406, the second sampled signal is converted with a second transconductance gain to obtain a second transconductance signal. In the abovementioned embodiment, the second transconductance gain has an optional denominator, which is used for determining the resolution of the fractional-N signal.

In step S407, a fractional-N phase error signal is generated by the difference between the first transconductance signal and the second transconductance signal. In the abovementioned embodiment, the difference between the two gains can improve both the resolution and the noise performance of the digital-to-time conversion circuit 317.

In step S408, the clock signal is generated using the fractional-N phase error signal. In the abovementioned embodiment, the loop filter 32 and the controllable oscillator 33 generate the clock signal based on the fractional-N phase error signal output from the subtractor circuit 313.

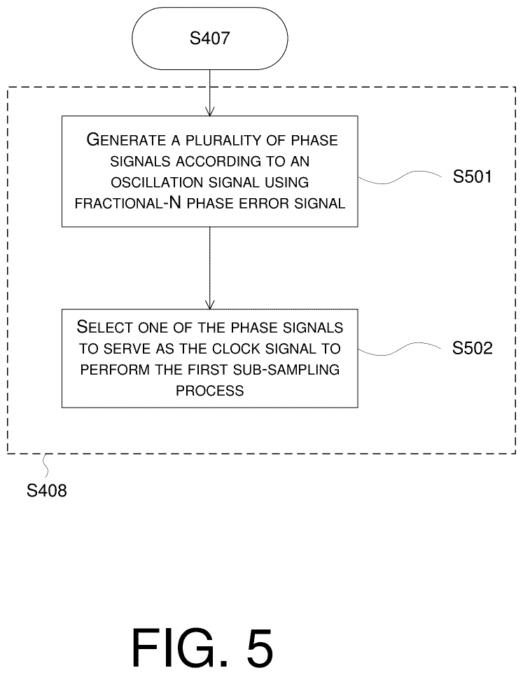

FIG. 5 illustrates a flowchart depicting the sub-steps of the step S408 in the method for generating a fractional-N clock in accordance with the present disclosure. Referring to FIG. 5, in this implementation, the step S408 of the method includes the following steps.

In step S501, a plurality of phase signals are generated according to an oscillation signal using the fractional-N phase error signal. In this embodiment, the delay-locked loop circuit DLL generates multiple phase signals based on the oscillation signal OS.

In step S502, one of the phase signals is selected to serve as the clock signal for performing the first sub-sampling process. As the abovementioned embodiment, the multiplexer MUX selects one of the multiple phase signals to serve as the clock signal CK based on an input code related to parameters such as the fractional ramp and the duty cycle calibration.

In summary, the present disclosure describes a fractional-N phase-locked loop (PLL) architecture designed for low-jitter applications. The architecture improves upon prior art by using a dual-path detection system to enhance the resolution of a digital-to-time conversion circuit. This improvement is crucial because, in conventional fractional-N PLLs, the quantization and thermal noise from the digital-to-time conversion circuit limit the PLL's bandwidth, forcing the voltage-controlled oscillator VCO to consume more power to meet noise targets. The disclosed dual-path detection implementation includes two main signal paths: the main path and the compensation path. The main path is used to create a fractional-N clock by delaying an oversampling signal based on a control signal generated from a fractional ramp. This delayed signal becomes the output clock signal. However, because of quantization errors in the system, the delay is not always perfect, which causes a small remaining error called residual error. In order to compensate for the residual error, the compensation path is added. It estimates the amount of residual error in the main path and then creates a compensation code to correct the error. This compensation code is used to control another delay path, which helps cancel out the residual error. However, the compensation path also introduces its own quantization error. To reduce the effect of this error, the system uses a delta-sigma modulation, which shifts the error noise to higher frequencies such that it can be more easily removed by filters. This helps improve the accuracy and performance of the overall system.

Furthermore, the disclosed implementation solves this issue by introducing a second split detection path to measure and amplify the residual quantization error by a factor of β. This effectively improves the native resolution and the noise performance by a factor of β, enabling the PLL bandwidth to increase without compromising performance. The system can also be implemented using well-known circuits such as a DLL and a multiplexer to generate and select from multiple phases, which helps to achieve higher resolution for fractional-N frequency.

### Additional Notes

The herein-described subject matter sometimes illustrates different components contained within, or connected with, different other components. It is to be understood that such depicted architectures are merely examples, and that, in fact, many other architectures can be implemented that achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically compatible and/or physically interacting components and/or wirelessly interactable and/or wirelessly interacting components and/or logically interacting and/or logically interactable components.

Further, with respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

Moreover, it will be understood by those skilled in the art that, in general, terms used herein, and especially in the appended claims, e.g., bodies of the appended claims, are generally intended as “open” terms, e.g., the term “including” should be interpreted as “including but not limited to,” the term “having” should be interpreted as “having at least,” the term “includes” should be interpreted as “includes but is not limited to,” etc. It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to implementations containing only one such recitation, even when the same claim includes the introductory phrases “one or more” or “at least one” and indefinite articles such as “a” or “an,” e.g., “a” and/or “an” should be interpreted to mean “at least one” or “one or more;” the same holds true for the use of definite articles used to introduce claim recitations. In addition, even if a specific number of an introduced claim recitation is explicitly recited, those skilled in the art will recognize that such recitation should be interpreted to mean at least the recited number, e.g., the bare recitation of “two recitations,” without other modifiers, means at least two recitations, or two or more recitations. Furthermore, in those instances where a convention analogous to “at least one of A, B, and C, etc.” is used, in general such a construction is intended in the sense one having skill in the art would understand the convention, e.g., “a system having at least one of A, B, and C” would include but not be limited to systems that have A alone, B alone, C alone, A and B together, A and C together, B and C together, and/or A, B, and C together, etc. In those instances where a convention analogous to “at least one of A, B, or C, etc.” is used, in general such a construction is intended in the sense one having skill in the art would understand the convention, e.g., “a system having at least one of A, B, or C” would include but not be limited to systems that have A alone, B alone, C alone, A and B together, A and C together, B and C together, and/or A, B, and C together, etc. It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

From the foregoing, it will be appreciated that various implementations of the present disclosure have been described herein for purposes of illustration, and that various modifications may be made without departing from the scope and spirit of the present disclosure. Accordingly, the various implementations disclosed herein are not intended to be limiting, with the true scope and spirit being indicated by the following claims.

What is claimed is:

1. A phase-locked loop (PLL) circuit, comprising:
a subsampling phase detection circuit, comprising:
a first sampling circuit, receiving a reference signal and a clock signal, configured to sample the clock signal using the reference signal and to output a first sampled signal;
a digital-to-time conversion circuit, receiving the reference signal, configured to generate a compensation signal according to a compensation code and the reference signal;
a second sampling circuit, receiving the reference signal and the compensation signal, configured to sample the compensation signal using the reference signal and to output a second sampled signal;
a first transconductance amplifier, receiving the first sampled signal, configured to amplify the first sampled signal with a first transconductance gain and to output a first transconductance signal;
a second transconductance amplifier, receiving the second sampled signal, configured to amplify the second sampled signal with a second transconductance gain and to output a second transconductance signal; and
a subtractor circuit, receiving the first transconductance signal and the second transconductance signal, configured to generate a fractional-N phase error signal;
a loop-filter, receiving the fractional-N phase error signal, configured to output a control signal; and
a controllable oscillator, receiving the control signal, configured to generate the clock signal according to the control signal.

2. The PLL circuit of claim 1, wherein the subsampling phase detection circuit further comprises:
a delta sigma modulation circuit, configured to generate the compensation code.

3. The PLL circuit of claim 1, wherein the second transconductance gain further comprises a denominator for determining a resolution of the compensation signal.

4. The PLL circuit of claim 1, wherein the controllable oscillator further comprises:
a voltage-controlled oscillator, configured to output an oscillation signal; and
a delay-locked loop, receiving the oscillation signal, configured to generate a plurality of phase signals from the oscillation signal to serve as the clock signal.

5. The PLL circuit of claim 4, wherein the controllable oscillator further comprises:
a multiplexer, configured to select one of the plurality of phase signals to be the clock signal received by the first subsampling circuit.

6. A method, comprising:
performing a first sub-sampling process to sample a clock signal using a reference signal and to output a first sampled signal;
generating a compensation signal according to a compensation code and the reference signal;
performing a second sub-sampling process to sample the compensation signal using the reference signal and to output a second sampled signal;
converting the first sampled signal with a first transconductance gain to obtain a first transconductance signal;
converting the second sampled signal with a second transconductance gain to obtain a second transconductance signal;
generating a fractional-N phase error signal by the difference between the first transconductance signal and the second transconductance signal; and
generating the clock signal using the fractional-N phase error signal.

7. The method of claim 6, wherein the compensation code is generated by a delta sigma modulation circuit.

8. The method of claim 6, wherein the second transconductance gain further comprises:
a denominator for determining a resolution of the compensation signal.

9. The method of claim 6, wherein the generating of the clock signal using the fractional-N phase error signal further comprises:
generating a plurality of phase signals according to an oscillation signal using the fractional-N phase error signal; and
selecting one of the phase signals to serve as the clock signal to perform the first sub-sampling process.

10. An integrated circuit, comprising:
a functional circuit, receiving a clock signal; and
a phase-locked loop (PLL) circuit, comprising:
a subsampling phase detection circuit, comprising:
a first sampling circuit, receiving a reference signal and a clock signal, configured to sample the clock signal using the reference signal and to output a first sampled signal;
a digital-to-time conversion circuit, receiving the reference signal, configured to generate a compensation signal according to a compensation code and the reference signal;
a second sampling circuit, receiving the reference signal and the compensation signal, configured to sample the compensation signal using the reference signal and to output a second sampled signal;
a first transconductance amplifier, receiving the first sampled signal, configured to amplify the first sampled signal with a first transconductance gain and to output a first transconductance signal;
a second transconductance amplifier, receiving the second sampled signal, configured to amplify the second sampled signal with a second transconductance gain and to output a second transconductance signal; and
a subtractor circuit, receiving the first transconductance signal and the second transconductance signal, configured to generate a fractional-N phase error signal;
a loop-filter, receiving the fractional-N phase error signal, configured to output a control signal; and
a controllable oscillator, receiving the control signal, configured to generate the clock signal according to the control signal.

11. The integrated circuit of claim 10, wherein the subsampling phase detection circuit further comprises:
a delta sigma modulation circuit, configured to generate the compensation code.

12. The integrated circuit of claim 10, wherein the second transconductance gain further comprises a denominator for determining a resolution of the compensation signal.

13. The integrated circuit of claim 10, wherein the controllable oscillator further comprises:
a voltage-controlled oscillator, configured to output an oscillation signal; and
a delay-locked loop, receiving the oscillation signal, configured to generate a plurality of phase signals from the oscillation signal to serve as the clock signal.

14. The integrated circuit of claim 13, wherein the controllable oscillator further comprises:
a multiplexer, configured to select one of the plurality of phase signals to be the clock signal received by the first subsampling circuit.
